(19) United States
(12) Patent Application Publication
(10) Pub. No.: US 2025/0081341 A1
(43) Pub. Date: Mar. 6, 2025

(54) Method and Apparatus of Conductive Hybrid Material Layer Stacks with Magnetic Material

(71) Applicant: Atlas Magnetics, Reno, NV (US)

(72) Inventor: John Othniel McDonald, Reno, NV (US)

(21) Appl. No.: 18/931,370

(22) Filed: Oct. 30, 2024

Related U.S. Application Data
(63) Continuation-in-part of application No. 18/135,660, filed on Apr. 17, 2023.
(63) Continuation-in-part of application No. 18/131,350, filed on Apr. 5, 2023.
(60) Provisional application No. 63/604,399, filed on Nov. 30, 2023.

(51) Int. Cl. H05K 1/09

(52) U.S. Cl. CPC H05K 1/09; H05K 2201/032; H05K 2201/083

(57) ABSTRACT

Presented herein is the apparatus and method of stacking magnetic materials with hybrid conductive materials. These methods and apparatus can be used in the formation of PCBs but are not limited to the formation of PCBs. The layer stacks presented within have a layer of conductive hybrid material and at least one layer of magnetic material. In at least one exemplary embodiment, these layers are adjacent in a layer stack, and the magnetic layer is a magnetic hybrid material.

### BACKGROUND

The field of invention generally and specifically relates to conductive and magnetic material layer stacks used generally in the field of microelectronics to build components. The inclusion of magnetic materials in layer stacks may be beneficial in a variety of circumstances, including improving inductance, shielding, filtering, and relays, for example. As such, it can be beneficial to include magnetic materials in everything from printed circuit boards (PCBs) to inductors and circuits in general.

It is well known that high-frequency currents will generate strong and tight eddy currents. As the frequency rises, the strength and tightness of the eddy currents will increase, meaning that the eddy currents are stronger and more localized to a specific area.

Traditionally, to handle eddy currents generated in circuits that require magnetic material, you could use a material that is resistant to current generation or could insulate those layers of magnetic material from each other. Using a magnetic material that is resistant to current typically required the use of a ferrite, which would place a very restrictive lower limit on the size of the component. Ferrites were also incompatible with traditional semiconductor fabrication processes and thus would add complexity to their integration. In many cases, metals were used, but as metals were not resistant to eddy currents, they had to be separated either by space or insulation.

Both ferrites and metals had limits as the current frequency rose. The insulation of metals had to get stronger, the metal layers smaller, while the space ferrites required for a high-frequency circuit were simply too much.

The formulation of conductive hybrid materials, which are low-cost and compatible with traditional semiconductor fabrication processes, allows more components to become high-frequency capable components. The lower cost and complexity of forming the conductive hybrid materials allow for these components to be integrated into consumer applications at a large scale. This means that there is now a need to incorporate conductive hybrid materials with traditional magnetic materials as well as new hybrid magnetic materials in a variety of components.

It is important to incorporate conductive hybrid materials with traditional magnetic materials because it opens the conductive hybrid materials to a wide range of components. Not all components that a conductive hybrid material is integrated into need to be able to handle high frequency.

A feature of conductive hybrid material is that the same amount of a conductive hybrid material as a traditional material will have much better high-frequency performance because the frequency per area performance is better. To get a performance similar to that of the conductive hybrid material as the traditional material, you can just run the current that the traditional material could take through it. But, if you just drop the current, you no longer need the conductive hybrid material to remain the same size as the traditional material. This means that using conductive hybrid material allows for smaller components at the same frequencies as those components would have been with traditional materials.

An example of this is a PCB trace, as a typical PCB trace thickness is in the order of 17.5 microns or ½ oz copper and is produced by electroplating or copper foil lamination. With a conductive hybrid material, for example, a copper hybrid material, each layer of copper is only 0.1 to 2 microns thick (usually selected to be 3 to 5× thinner than the skin depth of copper at the target frequency), and the porous insulator layers are around 30 to 200 nm thick. When those layers are built up so that the hybrid material is the same thickness as the traditional trace, the performance is much better than the traditional trace. However, the layer formation can be stopped at a point where performance is equal to the traditional material to make a much smaller trace.

It is good to be able to integrate the conductive material with traditional magnetic materials because it allows for smaller components without changing the requirements of the magnetic material of those systems. Not all microelectronics and semiconductor components need to be at the cutting edge of the industry in terms of performance. The auto industry, for example, has found older systems to be more than sufficient for their uses. Even so, by saving space and material costs, these older systems can be made at lower prices. Thus, it is beneficial to incorporate conductive hybrid materials into the systems alongside traditionally used materials.

At the cutting edge of the industry, high-frequency ability is sought after. Traditional magnetic materials cannot handle the frequencies that the conductive hybrid materials can, at the sizes they can, and are thus unable to fit within the parameters of a consumer device (for example, a mobile phone with ferrite used to handle high frequency would be far too large for its intended use.) Thus, it is also important to be able to integrate the conductive hybrid materials with magnetic hybrid materials to optimize performance.

It is not just simply performance that drives the desire to integrate but also fabrication complexities. For many high-frequency capable materials, there is a high complexity and cost to integrate those materials together into a cohesive system, and it is simply not done for consumer devices. For example, a single high-frequency laminated magnetic core that is capable of high frequency at a small size at the time of this writing can cost several thousand dollars. To put 12 of those cores into a single mobile phone would likely increase the price more than tenfold.

Therefore, there is a need to introduce conductive hybrid materials in systems with magnetic materials across the board, both literally and figuratively.

### BRIEF SUMMARY OF THE INVENTION

The present invention brings together conductive hybrid materials with magnetic materials, including hybrid magnetic materials. These layers stacks can be used in the formation of electrical system components.

Thus, presented herein is the apparatus and method of stacking hybrid magnetic materials with hybrid conductive materials. These methods and apparatus can be used in the formation of electrical components, including components for PCBs, transmission lines, inductors, relays, motors, generators, shielding, memory storage, transformers, sensors, and solenoids, but are not limited to use in these instances.

These apparatus and methods solve the complexity of integrating magnetic material into components because the fabrication processes for hybrid materials (i.e., hybrid magnetic materials and hybrid conductive materials) involve the plating through insulation layers, allowing for the removal of a majority of the intermediary steps involving the formation of solid insulation layers. This lowers the cost and complexity of forming usable layer stacks. The performance of the hybrid magnetic material with its thin, fine, porous insulation layers pairs well with the hybrid magnetic material, allowing optimal performance for both.

The apparatus presented herein is a layer stack of hybrid magnetic material and hybrid conductive layers. These layer stacks may incorporate additional layers, but fundamentally, the layer stack incorporates a magnetic material and a hybrid conductive material. By using a hybrid conductive material, the complexity of forming a magnetic material on the conductive layer is reduced. Even with the simple magnetic material, there are utilization benefits.

One layer stack presented herein is a hybrid conducive layer followed by a magnetic layer, for example, a NiFe layer. Another layer stack presented herein is a conductive hybrid material layer followed by a hybrid magnetic layer. These layers may be built directly on each other. These layer stacks may include further layers in the final stack, for example, a series of hybrid conductive material, magnetic material, and hybrid conductive material layers.

Therefore, presented herein is a layer stack comprising an initial layer of conductive magnetic material and at least one additional layer, the additional layers connected in series to the initial layer, where at least one of the additional layers is a magnetic material, as well as a method for forming said layer stack.

The conductive hybrid material of the initial layer of this layer stack may be a copper-based hybrid material. In one exemplary embodiment, at least one of the additional layers is a magnetic hybrid material. A magnetic hybrid material may be a nickel-iron (NiFe) based hybrid layer, while the magnetic layer may be a NiFe layer.

The layers of conductive material and magnetic material may be adjacent or separated by an insulator. However, a layer of porous insulation is not considered a separator when placed between layers because the layers will connect through the voids of the porous insulation layer.

At least one of the additional layers may be a conductive material, for example, copper or a copper-based hybrid material.

These layers may be formed in the process of building a PCB, for example, and, therefore, become integrated into the PCB, serving as, for example, traces or as the main layers of a multi-layer PCB. (It is worth noting that these layer stacks may also be formed on a PCB.)

In at least one exemplary embodiment, there are at least two additional layers operationally connected in sequence according to the sequence of a NiFE hybrid material followed by a copper hybrid material. This is an exemplary embodiment of a layer stack having layers of conductive hybrid material, magnetic hybrid material, and conductive hybrid material in sequence.

In at least one exemplary embodiment, there are at least two additional layers operationally connected in sequence according to the sequence of a NiFe layer followed by a copper hybrid material. This is an exemplary embodiment of a layer stack, having layers of conductive hybrid material, magnetic material, and copper hybrid material in sequence.

### BRIEF DESCRIPTION OF THE FIGURES

FIG. 1 is a perspective view of a two-layer exemplary embodiment of a layer stack having a conductive hybrid material and a magnetic material.

FIG. 2 is a perspective view of a two-layer exemplary embodiment of a layer stack having a conductive hybrid material and a magnetic hybrid material.

FIG. 3 is a perspective view of a layer stack of repeating conductive hybrid material layer and a magnetic layer; as shown, it is a series of copper hybrid material and NiFi layers.

FIG. 4 is a perspective view of a layer stack with a conductive hybrid layer, a magnetic layer, and a general additional layer.

FIG. 5 is a perspective view of a layer stack of repeating conductive hybrid material layer and a magnetic hybrid layer; as shown, it is a series of copper hybrid material and NiFi hybrid layers.

FIG. 6 is a perspective view of a layer stack of repeating conductive hybrid material layers and a magnetic hybrid layer in series, as shown, with an additional insulating layer within the series.

FIG. 7 is a perspective view of a layer stack of a conductive hybrid material layer and a magnetic hybrid layer integrated into a printed circuit board.

FIG. 8 is a perspective view of a layer stack of a conductive hybrid material layer and a magnetic hybrid layer integrated into a multi-layer printed circuit board.

FIG. 9 is a perspective view of a layer stack of a conductive hybrid material layer and a magnetic hybrid layer integrated into a multi-layer printed circuit board where the conductive hybrid materials and the magnetic materials are not adjacent.

FIG. 10 is a perspective view of a layer stack of a conductive hybrid material layer and a magnetic hybrid layer on two sides of a PCB.

FIG. 11 is a perspective view of a drilled layer stack of a conductive hybrid material layer and a magnetic hybrid layer on two sides of a PCB.

FIGS. 12a and 12b are a flowchart of a method of making a layer stack of the present invention.

### DETAILED DESCRIPTION OF THE INVENTION

Described herein is a layer stack, the layer stack having a layer of conductive hybrid material and at least one layer of magnetic material. In at least one exemplary embodiment, the conductive hybrid material and the magnetic layer are adjacent in the stack. Thus, one potential stack of layers is a series of layers as follows: a conductive hybrid material, a magnetic material, and a conductive hybrid material, for example, a copper hybrid material, a nickel-iron (NiFe), and a copper hybrid material. Another potential stack is a conductive hybrid material, magnetic hybrid material, and a conductive hybrid material, for example, a copper hybrid material, a NiFe hybrid material, and a copper hybrid material. These stacks are beneficial in the formation and use of electrical components.

These layer stacks are amiable to a wide variety of integrations and design considerations. Consider the use case of transmission lines. A transmission line may incorporate magnetic shielding to prevent external electromagnetic interference and reduce crosstalk; in general, this enhances signal integrity and increases efficiency. This magnetic shielding is typically laminated, spaced at intervals, or shaped to reduce eddy current generation and the negative effects of ferromagnetic resonance (FMR) from the shielding.

The present invention of layer stacks, as described herein, may be integrated into these existing transmission lines in a variety of ways. It is worth exploring these ways to get a sense of how adaptable hybrid materials are and the many ways layer stacks incorporating them can be used.

A transmission line of the present invention may consist of a layer of conductive material, for example, hybrid conductive material, and use a traditional magnetic material as shielding. If the transmission line is intended to handle high frequency, several options may be applied. One option is to pattern the magnetic material as would be found on a traditional transmission line, which is patterned to reduce eddy currents and the impact of FMR. For example, instances of the magnetic material can be spaced apart by insulation or lamented to reduce eddy currents and laid out in a specific pattern to reduce FMR. Essentially, the hybrid conductive material of the transmission line is compatible with existing magnetic shielding and practices.

However, a magnetic hybrid material may be used as the shielding. In such a case, a layer of the magnetic hybrid material may simply be placed over the transmission line so that the magnetic hybrid material covers the transmission line. By greatly reducing the eddy current strength, the magnetic hybrid material works to prevent power loss in the magnetic shielding, thus greatly improving the system even without accounting for FMR. However, because the magnetic hybrid materials are compatible with most fabrication processes, they can be patterned to reduce the FMR as well. Not only can they be patterned, but they can be layered as a traditionally laminated metal might be. This means that the magnetic hybrid material can be used in the same patterns, with the same design considerations for reducing eddy currents and FMR as the traditional material can. However, there may be some downsides to this approach, which will be discussed more in-depth below.

It will be appreciated that there is a balance when it comes to integrating the hybrid material with insulative laminations as opposed to simply utilizing the hybrid magnetic material without additional laminations. The laminations may increase the resistance to eddy currents, but they will also affect the thickness, the cost, the complexity, and the ability to alter the magnetic shielding after placement. Traditional laminations are solid, non-porous insulation layers that distinctly delineate the magnetic material into layers. Thus, each magnetic layer in the laminated magnetic shielding will have its own skin depth and the like. The laminations add complexity to the fabrication process as additional steps must be directed towards both forming the insulating lamination and bonding the magnetic layers onto the insulation layers. Further, the presence of these traditional insulation layers increases the complexity and cost of any subtractive formation of patterns as the insulation layers tend to be drill and etch-resistant.

It is worth noting as well that at higher frequencies, as noted above, the laminations must be closer together to effectively reduce the eddy currents. Once the frequency gets high enough, the practicality of incorporating laminations decreases as the space between each insulation layer must be thinner and thinner, which increases the complexity of fabricating the shielding. So, although traditional insulation can be used to separate layers of magnetic hybrid material (e.g., a magnetic hybrid material: traditional insulation: magnetic hybrid material layer pattern) it is not usually worth it.

Magnetic hybrid material is comparatively far less complex to form patterns than traditional magnetic layering or shielding. It can be formed in a pattern in an additive manner or in a subtractive manner. Like a traditional lamination, it can be patterned layer by layer in an additive manner as it is built up. It can be built up faster because there are no traditional lamination layers with extra process steps; instead, with magnetic hybrid materials, insulation is typically sprayed on a recipient layer, and then a subsequent layer is plated directly on the insulation so that it bonds with the recipient layer through pores in the insulation. In many cases, patterns with magnetic hybrid materials can also be formed by subtractive means. This is enabled when the insulation material within the magnetic hybrid material is a porous insulation material formed as a series of particulates. These particulates will wash away in an etch that etches the base material (e.g., copper for copper-based conductive hybrid material) and will also be ejected by a drill or grinder with the swarf.

As will be discussed in more detail below in relation to printed circuit boards, subtractive pattern formation allows for patterns to be edited or formed after manufacturing, for example, by a customer.

Thus, we can see a component can integrate with hybrid materials utilizing traditional magnetic materials and patterning. A component can also integrate with a hybrid magnetic material, where the hybrid magnetic material is patterned and insulated as the traditional magnetic material. A component can also integrate the hybrid magnetic material without laminations or spacing, as would typically be required for high-frequency applications with traditional materials. If the latter is done, the hybrid magnetic material provides a simpler medium to alter.

Essentially, the incorporation of the hybrid material into the layer stack allows for magnetic material to be utilized in electrical component construction efficiently while reducing the complexity of both building the component and reducing the effort required to alter the component after fabrication. As the insulation of the hybrid layers allows for low-cost fabrication while also reducing the proliferation of eddy currents between layers. By using hybrid layers, the layers are drillable or etchable because the insulation, typically resistant to drilling or etching processes, is in a particle form and will be washed out or easily moved out by the etching or drilling process. This reduces the need for alternate insulation layer-specific drilling processes.

The ability of the present invention to integrate into existing systems means that there are many possible layer stacks. The conductive hybrid material is equally adept at integrating into a system that uses traditional, hybrid, or other advanced magnetic materials, allowing for a wide array of use cases. Several of these will be discussed later on.

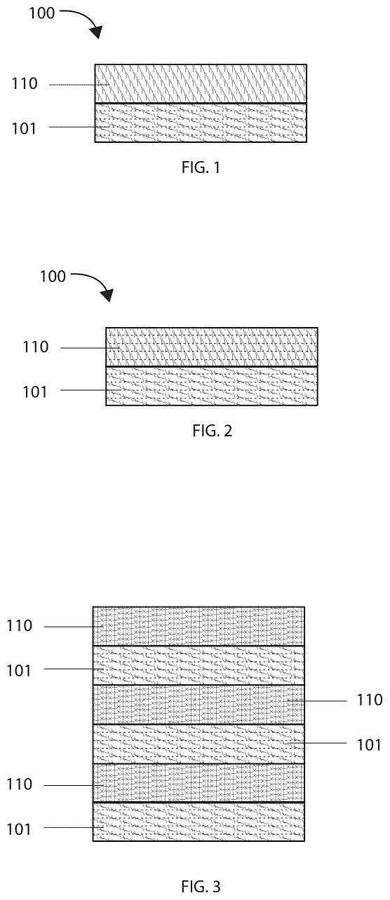

FIG. 1 shows a layer stack 100 of the present invention with a conductive hybrid material 101 and a magnetic material 110. This is the simplest embodiment of the present invention. The conductive hybrid material may be, for example, a conductive hybrid material, and the magnetic material may be, for example, a nickel ion (NiFe). There are many materials that the layer types may be, but in general, metals and metal alloys, which are conductors and/or highly permeable to magnetic flux, respectively, form excellent embodiments.

FIG. 2 shows the layer stack of FIG. 1, wherein the magnetic layer 110 is now a hybrid magnetic layer 111, which is a subtype of the magnetic layer. The hybrid magnetic layer will typically provide better performance than a non-hybrid magnetic layer.

It will be appreciated that only two layers are necessary to form a layer stack. A two-layer stack is a subset of a layer stack comprising conductive hybrid material and at least one additional layer, the additional layers connected in series to the initial layer, where at least one of the additional layers is a magnetic material. Here, there needs to be only one conductive hybrid material layer, one magnetic layer, and one layer in addition to the conductive hybrid material. Thus, in a two-layer stack, the one magnetic layer becomes the one additional layer, which is connected to the one conductive hybrid layer. This stack forms a sequence of conductive hybrid material and magnetic material, and this sequence may be repeated as desired, with the final layer being either a conductive hybrid material, a magnetic material, or an additional material to serve as an end layer. (An end layer may be helpful when the layer stack is integrated into a PCB).

It is worth noting here that it is possible to introduce alternate layers into a layer stack, including for secondary purposes, for example, controlling thermal expansion. The insulation layers of the hybrid material allow for direct deposition of adjacent layers as long as the adjacent layer can be formed on the hybrid material. In some cases, a void-less insulation layer may be included in the layer stack as desired. This may remove some of the benefits related to the handling of the resulting layer stack, for example, the ability to quickly drill the layer stack, but it may improve the performance. There are a myriad of possible layer stacks, and a few demonstrative embodiments will now be discussed.

FIG. 3 shows a layer stack with multiple layers of conductive hybrid material 101 and multiple layers of magnetic material 110.

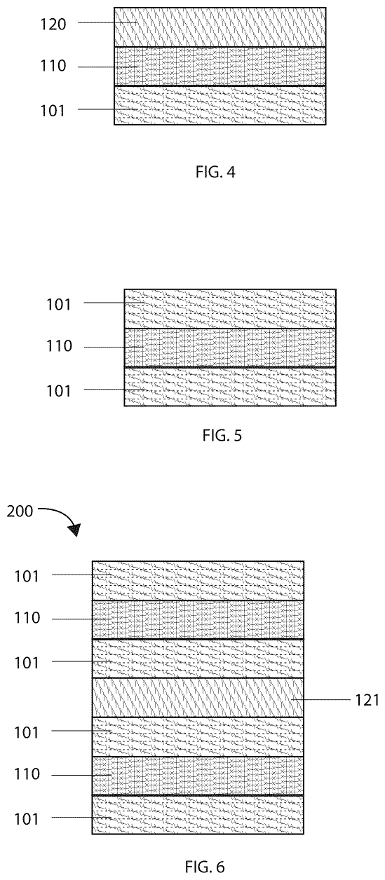

A layer stack may also have an additional layer that is not hybrid or magnetic. FIG. 4 shows such a layer stack with an additional layer 120 operably connected to magnetic layer 110, which is operably connected to conductive hybrid layer 101. However, when referenced herein, the additional layer may be either a conductive hybrid material or a magnetic material, but across embodiments, it is not limited to these layer types. In FIG. 5, the additional layer 120 is now a conductive hybrid material layer 101.

Alternate layers, besides hybrid layers of magnetic layers, may be useful, for example, an insulation, or substrate layer. FIG. 6 shows a layer stack 200 of conductive hybrid material 101 and magnetic material 110 with an additional layer of insulation 121 dividing the stack.

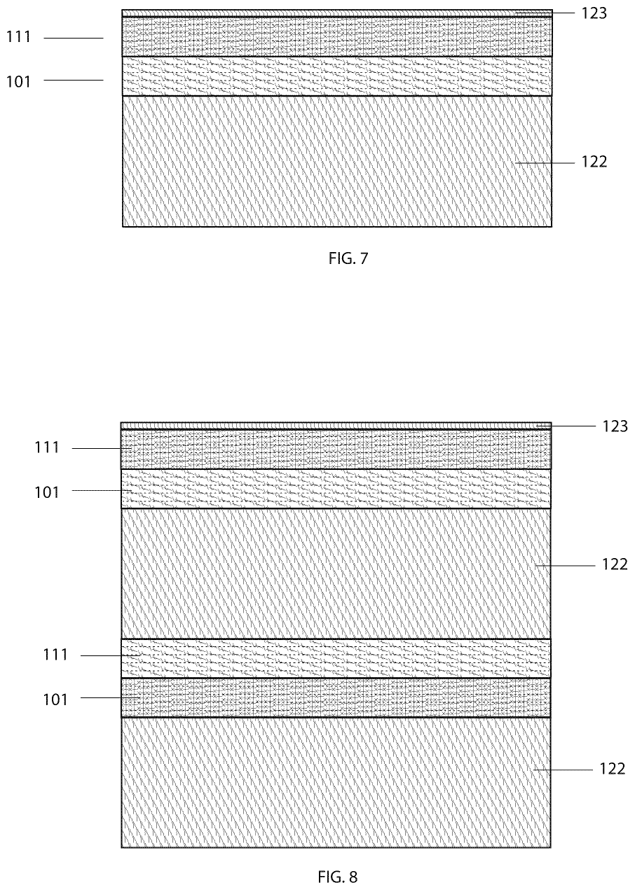

These layer stacks can be integrated into or onto many components, including wafers, semiconductor packaging, flex circuits, and PCBS. Here, we will look at integration into a PCB. For example, FIG. 7 shows a section of an integrated layer stack of copper hybrid material 101 and a NiFe hybrid material 111 on a layer of PCB Substrate 122 with a solder mask end layer 123. The layer stack here is forming the PCB itself.

The layers stacks can also be incorporated into multilayer PCBs. In at least one exemplary embodiment, PCB substrate layers serve as at least one of the additional layers. FIG. 8 shows an exemplary layer stack integrated into a PCB, comprising a repeating series of hybrid magnetic layers, hybrid conductive layers, and a PCB substrate.

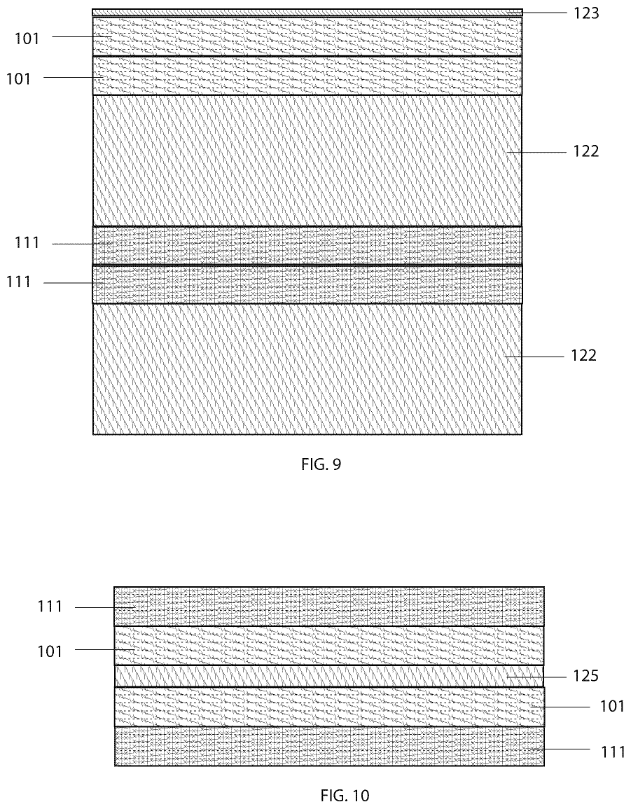

In a PCB the magnetic layers and the conductive hybrid layers need not be adjacent in all embodiments and may be separated by at least one additional layer, for example, a PCB substrate layer; such a configuration is shown in FIG. 9. Here, the magnetic hybrid layers 111 are separated from the conductive hybrid layers 101 by PCB layers 122.

Layer stacks can also be formed on the surface of a PCB. Layer stacks incorporating hybrid and/or metal layers provide layers that are not task-intensive to shape as desired. FIG. 10 shows a layer stack of hybrid magnetic layer 111 and hybrid conductive layers 101 on a PCB board 125.

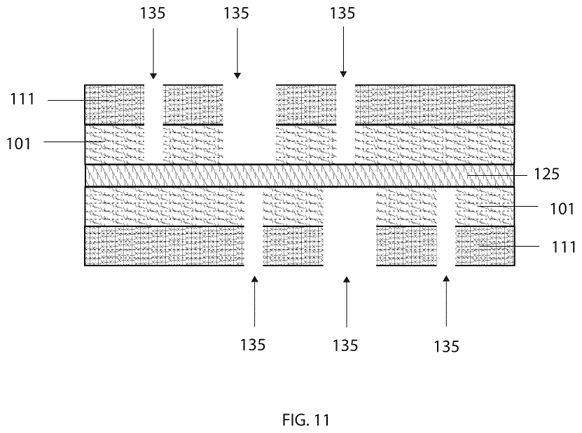

These magnetic hybrid layers and hybrid conductive layers may be drilled as their regular metal counterparts would be, something not generally possible with traditional laminated layer stacks. FIG. 11 shows a drilled form of the layer stack on a PCB. Where drill holes 135 pierce through conductive hybrid material layers 101 and hybrid magnetic layers 111.

The ease of utilizing a subtractive process with hybrid material layers stacks is useful for patterning the layers stacks. With the ease of using subtractive processes, it is possible for one company to form the layer stacks and another to pattern the layer stacks. For example, a customer buys a mass-produced PCB with a certain layer order and then patterns the layers according to their needs or desires.

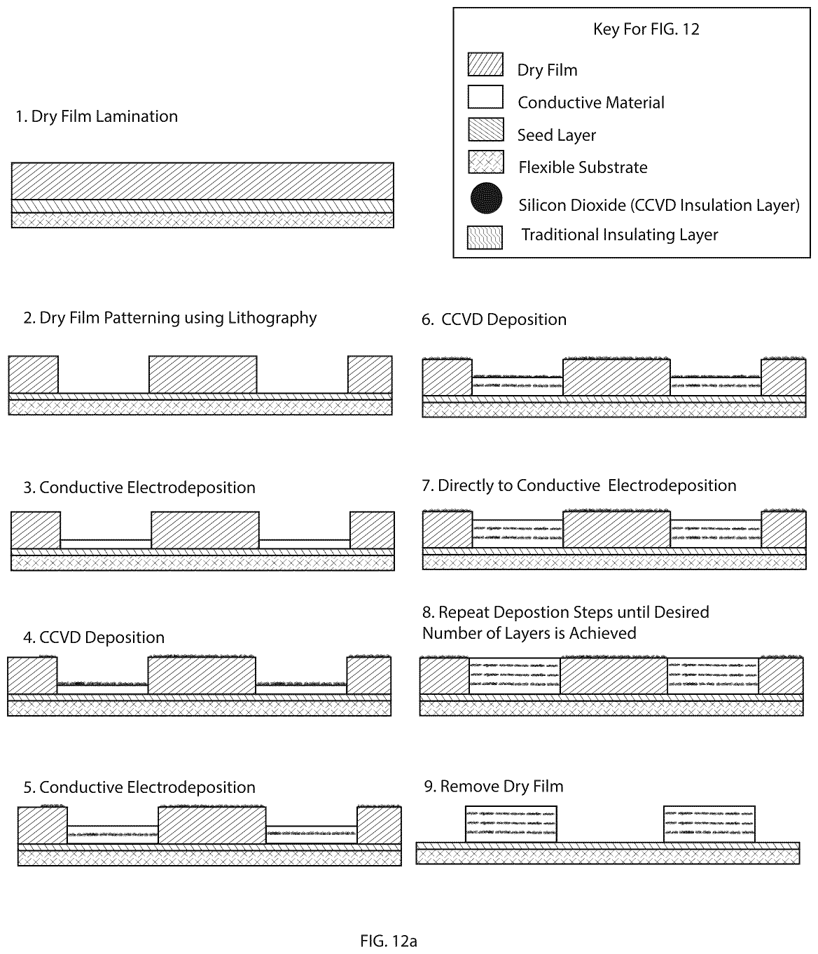

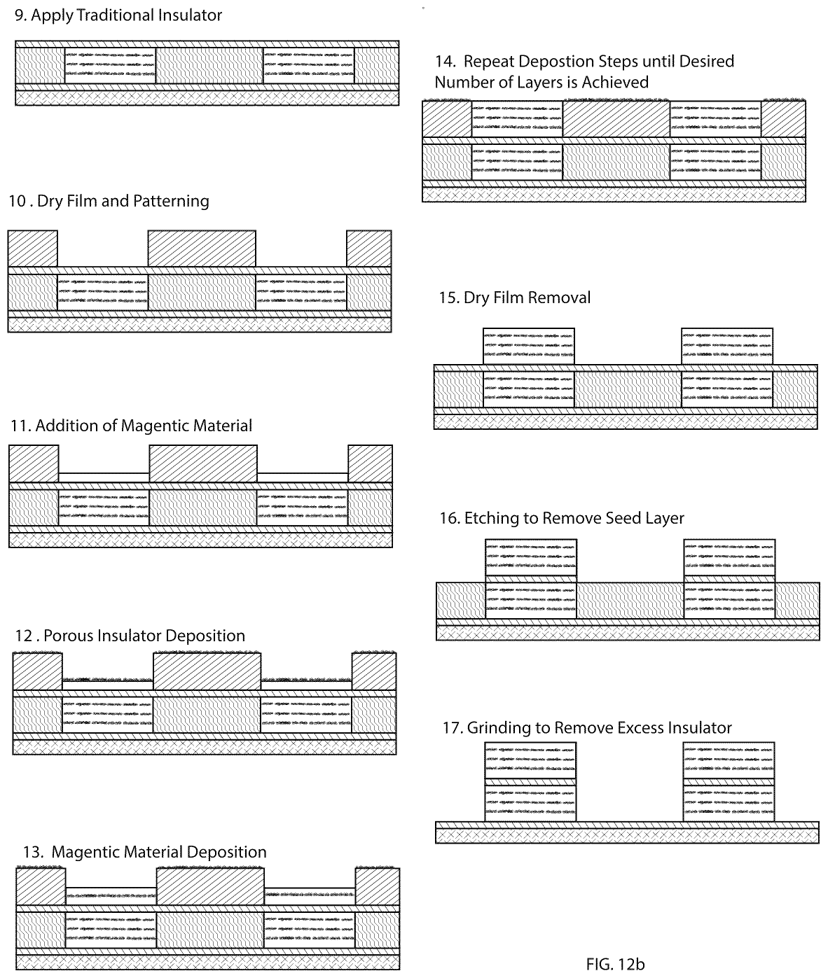

However, additive processes can be used to form and pattern layers as well. FIG. 12a and FIG. 12b show an additive process for a layer stack formed on a flexible circuit substrate, for example, a polyether ether ketone-based substrate. The additive process is a low-step process compared to the manufacturing of traditional flexible laminated magnetic components.

The process starts with a patterning process on a seed layer for the initial layer. This is followed by the formation of the initial layer, which is a conductive hybrid material here. The conductive hybrid material is deposited according to the preformed pattern (if any pattern is desired). Once the layer is complete, the dry film is removed, and a substrate or carrier material is placed to support the next layer. The subsequent layer is patterned if desired and maybe, but need not be, patterned according to a different pattern than the initial layer. This process can be repeated for the entirety of the layer stack.

The drawings and figures show multiple embodiments and are intended to be descriptive of particular embodiments but not limited to the scope, number, or style of the embodiments of the invention. The invention may incorporate a myriad of styles and particular embodiments. All figures are prototypes and rough drawings: the final products may be more refined by one skill in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms. The term “metal” is defined as a metal or an alloy thereof.

1. A layer stack comprising:
a layer of conductive hybrid material; and
at least one additional layer, the additional layers operably connected in a stack to the layer of conductive hybrid material, where at least one of the additional layers is a magnetic material.

2. The layer stack of claim 1, wherein the conductive hybrid material is a copper-based hybrid material.

3. The layer stack of claim 1, wherein at least one of the additional layers is a magnetic hybrid material.

4. The layer stack of claim 3, wherein at least one of the additional layers of magnetic hybrid material and conductive hybrid material are adjacent.

5. The layer stack of claim 1, wherein at least one of the additional layers is a conductive hybrid material.

6. The layer stack of claim 3, wherein the magnetic hybrid material is a NiFe-based hybrid magnetic material.

7. The layer stack of claim 1, wherein the magnetic material is a NiFe magnetic material.

8. The layer stack of claim 1, further comprising the layer stack operationally integrated into a printed circuit board.

9. The layer stack of claim 1, wherein there are at least two additional layers operationally connected in sequence according to a sequence of a NiFE hybrid material followed by copper hybrid material.

10. The layer stack of claim 1 wherein there are at least two additional layers operationally connected in sequence according to the sequence of a NiFe followed by copper hybrid material.

11. A method of forming a layer stack comprising:
forming an initial layer of conductive magnetic material; and
forming at least one additional layer, where at least one of the additional layers is a magnetic material, and the additional layers are operably connected in series incorporating the initial layer.

12. The method of forming a layer stack of claim 11, wherein the conductive hybrid material used to form the initial layer is a copper-based hybrid material.

13. The method of forming a layer stack of claim 11, wherein at least one of the additional layers formed is a magnetic hybrid material.

14. The method of forming a layer stack of claim 13, wherein at least one of the formed layers of magnetic hybrid material and conductive hybrid material are adjacent.

15. The method of forming a layer stack of claim 11, wherein at least one of the additional layers formed is a conductive hybrid material.

16. The method of forming a layer stack of claim 13, wherein the magnetic hybrid material used to form at least one of the layers of magnetic material is a NiFe-based hybrid magnetic material.

17. The method of forming a layer stack of claim 11, wherein the magnetic material used to form at least one of the magnetic layers is a NiFe magnetic material.

18. The method of forming a layer stack of claim 11, further comprising operationally integrating the layer stack integrated into a printed circuit board.

19. The method of forming a layer stack of claim 11, wherein there are at least two additional layers formed operationally connected in sequence according to the sequence of a NiFe hybrid material followed by a copper hybrid material.

20. The method of forming a layer stack of claim 11, wherein there are at least two additional layers formed operationally connected in sequence according to the sequence of a NiFe followed by a copper hybrid material.
